(19) United States
(12) Patent Application Publication
(10) Pub. No.: US 2022/0367754 A1
(43) Pub. Date: Nov. 17, 2022

(54) MONOLITHIC COLOR-TUNABLE LIGHT EMITTING DIODES AND METHODS THEREOF

(71) Applicant: INNOVATION SEMICONDUCTOR, Rochester, NY (US)

(72) Inventor: Matthew T. HARTENSVELD, Wyckoff, NJ (US)

(21) Appl. No.: 17/691,934

(22) Filed: Mar. 10, 2022

Related U.S. Application Data
(60) Provisional application No. 63/188,553, filed on May 14, 2021.

(51) Int. Cl. H01L 33/24; H01L 33/00; H01L 33/06; H01L 33/14; H01L 33/32

(52) U.S. Cl. CPC H01L 33/24; H01L 33/007; H01L 33/06; H01L 33/145; H01L 33/32

(57) ABSTRACT

A monolithic LED system that is configured to emit a variety of peak wavelengths of light in response to variations in a driving current density includes an n-type region, a p-type region, and a multiple quantum well (MQW) region formed between the n-type region and the p-type region. The MQW region includes parallel layers, each doped with a percentage of Indium to enable a range of light emission between 400 and 600 nm, and one or more V-grooves formed within a portion of the parallel layers. Each of the one or more V-grooves has a lower concentration of the doped percentage of the Indium than other portions of the parallel layers. Transition regions between the one or more V-grooves and the other portions of the parallel layers have a higher concentration of the doped percentage of the Indium which decreases with distance from the one or more V-grooves.

This application claims the benefit of Provisional Patent Application Ser. No. 63/188,553, filed May 14, 2021, which is hereby incorporated by reference in its entirety.

### FIELD

This technology relates to monolithic color-tunable light emitting diodes and methods thereof.

### BACKGROUND

Conventional light-emitting diodes (LEDs) are composed of various layers. These layers include an electron rich n-type region, a hole rich p-type region, and a multiple quantum well (MQW) region between the n-type and p-type regions. The MQW region is composed of multiple individual quantum wells which possess a smaller energy bandgap due to alloying, that are positioned between higher energy bandgap materials. The smaller energy bandgap quantum wells confine electrons and holes to facilitate recombination and corresponding light emission.

By way of example for LEDs based on the III-N material system, Indium is alloyed with GaN in different amounts to shrink the bandgap of the quantum wells. Where blue light can be produced with quantum wells containing ˜10% Indium, additional Indium incorporation leads to longer wavelength emissions. Unfortunately, as the Indium concentration continues to increase, issues of strain, solubility, and corresponding low efficiency arise. These issues make the realization of red LEDs particularly challenging in the III-N material system which forms the basis of commercial blue and green LEDs.

Emission of different desired wavelengths from a single LED material system or packaged product is desired for several different commercial devices and application. One such application is the formation of white light, where white light requires the mixing of three primary colors: red, green, and blue. Equal proportions of each produce white light, while non-equal proportions can produce any range of colors in the visible spectrum, e.g. red and blue make purple.

LEDs used in commercial white lighting are conventionally blue LEDs with InGaN/GaN MQWs paired with a phosphor coating which absorbs some blue and generates green and red light. Together the red, green, and blue wavelengths produce white light. For further LED applications in displays, or for the ability to generate a desired emission color of lighting, multiple different individual LEDs are utilized.

Typically, separate InGaN/GaN LEDs are used for blue and green, and GaAs based LEDs are used for red. Unfortunately, the use of several LEDs to emit separate colors mean increased fabrication costs and increased complexity to integrate these three different types of LEDs.

To get around challenges of integrating different types of MQW regions in a single growth process to emit different colors, prior monolithic approaches commonly relied on the use of patterned color converters, such as quantum dots (QDs) or phosphors. These localized color converters absorb higher energy blue to make green or red for separate LEDs fabricated on the same wafer. Use of color converters can eliminate the need for other material systems, though still represent added manufacturing steps and cost. Color converters also do not have 100% efficiency and can lead to slight losses.

As stated earlier, InGaN/GaN LEDs already offer blue and green colors, though red represents a challenge. The wavelength of emission, i.e. the color, is determined through the percentage of Indium in the InGaN/GaN MQWs. Blue LEDs are ˜10% Indium, green LEDs ˜20%, red LEDs ˜40%. There are diminishing returns for Indium incorporation as there are limits with GaN growth temperatures, along with issues of high lattice strain.

Initial attempts to incorporate high indium concentrations have led to poor efficiency due to large internal band bending caused by strain, along with numerous point defects. Nanowire growth shows the potential to form color-tunable LEDs through tailoring the diameter of the nanowires to incorporate different levels of Indium. The strain is able to be released through the sidewalls of the structure when making use of a vertical nanowire format in contrast to a planar design. Nanowire epitaxial growth however may result in yield issues and a general incompatibility with current semiconductor processes or architecture.

Alternatively, there also has been work done introducing Europium (Eu) into the GaN lattice which acts as an optical mid-gap state. This approach involves Eu incorporation into a section of the LED to produce red light, instead of relying on InGaN/GaN MQWs for red light. Separate LED growths can be done to form blue MQWs, then green MQWs, then Eu-doped red regions on top of each other, where selective etching is used to fabricate full color monolithic devices. While at a research scale for planar devices the approach has been realized, Eu remains a rare element, that is questionable for use in large-scale manufacturing, with remaining issues of light generation efficiency.

Accordingly, as discussed above each of these available prior options creates some level of sacrifice which are non-ideal for large scale commercial manufacturing.

### SUMMARY

A monolithic LED system that is configured to emit a variety of peak wavelengths of light in response to variations in a driving current density includes an n-type region, a p-type region, and a multiple quantum well (MQW) region formed between the n-type region and the p-type region. The MQW region includes parallel layers, each doped with a percentage of Indium to enable a range of light emission between 400 and 600 nm, and one or more V-grooves formed within a portion of the parallel layers. Each of the one or more V-grooves has a lower concentration of the doped percentage of the Indium than other portions of the parallel layers. Transition regions between the one or more V-grooves and the other portions of the parallel layers have a higher concentration of the doped percentage of the Indium which decreases with distance from the one or more V-grooves.

A method for making a monolithic LED system configured to emit a variety of peak wavelengths of light in response to variations in a driving current density includes forming one of an n-type region or p-type region. A MQW region is formed on the one of the n-type region or the p-type region. The MQW region includes parallel layers, each doped with a percentage of Indium to enable a range of light emission between 400 and 600 nm and one or more V-grooves formed within a portion of the parallel layers. A portion of the parallel layers in each of the one or more V-grooves has a lower concentration of the doped percentage of the Indium than the other portions of the parallel layers. Transition regions between the portion of the parallel layers in each of the one or more V-grooves and the other portions of the parallel layers has a higher concentration of the doped percentage of the Indium which decreases with distance from the one or more V-grooves. The other one of the n-type region or the p-type region is formed on the MQW region.

This technology provides a number of advantages including providing a monolithic multi-color LED system which may be effectively utilized in a number of different applications, such as displays, commercial lighting, communications, and more. In particular, examples of this technology provide a monolithic integration of color-selectable LEDs without requiring any color converters which reduces complexity, offers better performance, and lowers cost for many applications. Monolithic is defined for some examples herein as the same InGaN/GaN, III-N, material system used within the same wafer. Examples of the claimed technology are further able to provide monolithic color-tunable LEDs without Eu doping, growth of separate MQW regions, or increased planar Indium percentage. Further, with examples of this technology LEDs as small as two (2) microns in diameter having at least one V-groove contained within can be manufactured.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1 is a cross-sectional diagram of an example of a monolithic color-tunable LED system;

FIG. 2 is a cross-sectional image of an example of another monolithic color-tunable LED system;

FIG. 3 is a cross-sectional image of yet another example of a monolithic color-tunable LED system overlaid with rough estimates on the areas of Indium and Aluminum;

FIG. 4 is a graph of an example of current densities utilized in order to produce different desired color emissions from ˜640 nm down to ˜425 nm to span the visible spectrum, from an exemplary monolithic color-tunable LED system;

FIG. 5 is a graph of an example of cathode luminescence (CL) emission.

### DETAILED DESCRIPTION

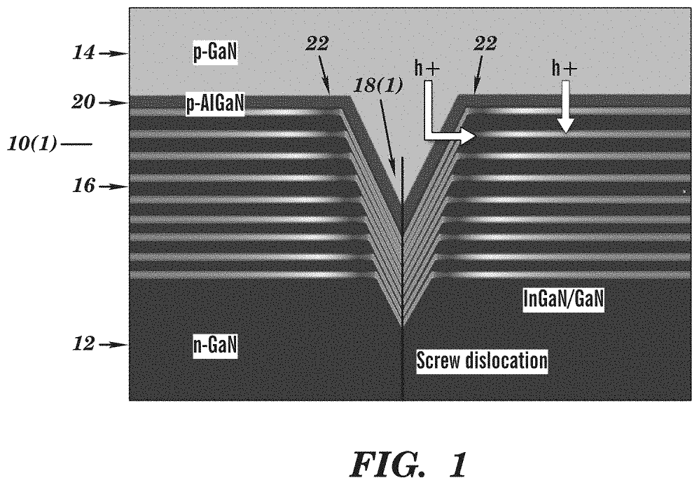

An example of a monolithic color-tunable LED system 10(1) in accordance with examples of this technology is illustrated in FIG. 1. In this example, the monolithic color-tunable LED system 10(1) includes an n-type region 12, a p-type region 14, and a multiple quantum well (MQW) region 16 with a V-groove 18(1), and an electron blocking layer (EBL) 20, although the system can includes other types and/or numbers of other layers or other elements. This technology provides a number of advantages including providing a monolithic multi-color LED system which may be effectively utilized in a number of different applications, such as displays, commercial lighting, communications, and more.

Referring more specifically to FIG. 1, the monolithic color-tunable LED system 10(1) is configured to emit a variety of peak wavelengths of light in response to variations in a driving current density. In this example, the monolithic color-tunable LED system 10(1) comprises the p-type layer 14 on the EBL layer 20 on the MQW region 16 on the n-type layer 12, although the system may comprise other types and/or numbers of layers and/or other elements in other configurations, such as having an initial growth substrate layer by way of example.

In this example, the n-type layer 12 comprises an n-type GaN layer, although other types and/or numbers of layers may be used. The MQW region 16 is on the n-type GaN layer and includes parallel layers of GaN, each doped with a percentage of Indium to enable a range of light emission between 400 and 600 nm and with a V-groove 18(1) formed within a portion of the parallel layers, although the MQW region may have other types and/or numbers of layers with other dopants and/or other numbers of V-grooves. A portion of the parallel layers of the MQW region 16 located in the V-groove 18(1) has a lower concentration of the doped percentage of the Indium than other portions of the parallel layers of the MQW region 16 located outside of the V-groove 18(1). These other portions of the parallel layers of the MQW region 16 outside of the V-groove 18(1) are also referred herein as the planar MQWs. Additionally, in this example transition regions 22 between the portion of the parallel layers in the V-groove 18(1) and the other portions of the parallel layers located outside of the V-groove 18(1) have a higher concentration of the doped percentage of the Indium which decreases in the other portions of the parallel layers with distance from the V-groove 18(1).

The EBL layer 20 is a p-type GaN layer and is located on the portion of the parallel layers in the V-groove 18(1) and on the other portions of the parallel layers outside of the V-groove 18(1), although other types and/or numbers of layers may be used. By way of example, the p-type EBL 20 could be a 5% Aluminum containing p-AlGaN layer, although other types and/or numbers of electron blocking layers can be used. Next, the p-type GaN layer 14 is on the p-type EBL 20, although other types and/or numbers of layers may be formed.

In this example, to create this monolithic color-tunable LED system 10(1) the n-GaN layer 12 is formed on an initial growth substrate (not shown in FIG. 1), such as sapphire by way of example, leading to an imperfect match due to the differences in each lattice constant is used. The underlying growth before the InGaN layers of the MQW region 16 are grown determines a density of threading dislocations.

Next, the MQW layers of the MQW region 16 comprising parallel layers of GaN each doped with a percentage of Indium to enable a range of light emission between 400 and 600 nm are grown on the n-GaN layer 12 are grown on the n-GaN layer 12.

During the growth of this MQW region 16 the V-groove 18(1) is formed. A selected percentage of Indium (which increases strain), such as 18% by way of example, can be utilized to achieve formation or integration of this V-groove 18(1) from a threading dislocation. This formation is due to the strain created by incorporating the Indium, along with the reduced growth temperature.

Next, a p-type EBL 20 is grown on the portion of the parallel layers in the V-groove 18(1) and on the other portions of the parallel layers outside of the V-groove 18(1) of the MQW region 16.

Next, the p-type GaN layer 14 is grown on the EBL 20 in this example. When the higher temperature p-GaN 14 is grown on top, the higher surface mobility leads to the V-groove 18(1) filling in. The growth conditions right before the MQW region 16, such as use of a super lattice or lack thereof, along with managing corresponding growth temperatures, lead to control over the lateral size of the V-groove 18(1) in this example, through reduced compressive stress.

Once the monolithic color-tunable LED system 10(1) is grown, LEDs or other optoelectronic devices can, for example, be fabricated. For LED formation, patterning specific areas can be done with photolithography, where photoresist acts as a mask. Dry etching can then be used to selective remove the p-type layer 14 and MQW region 16, where there is no photoresist, to then access the n-type GaN layer 12. The etching process forms the individual LED structures. Additionally, a top metal or other conductor (not shown) can be deposited on the p-type GaN layer 14, forming the anode. Followed by another metal layer or other conductor (not shown) deposited on the n-type GaN layer 12 which be utilized as the cathode.

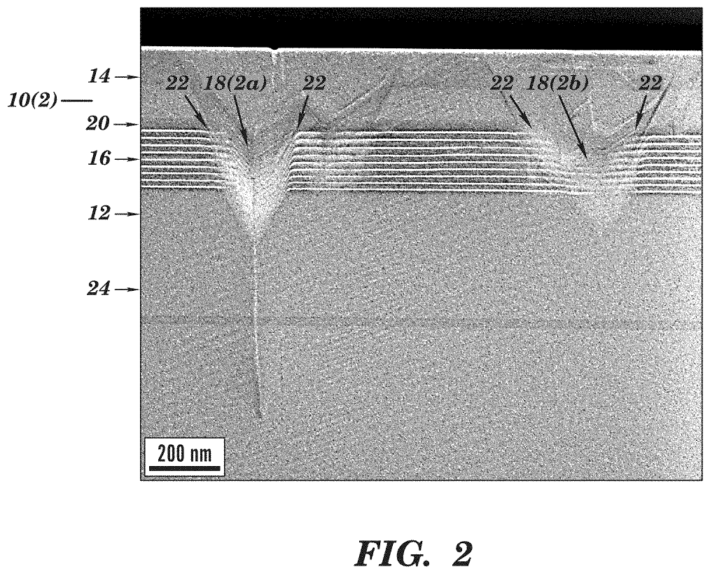

Referring to FIG. 2, another example of a monolithic color-tunable LED system 10(2) is illustrated. This example of the monolithic color-tunable LED system 10(2) is the same in structure, formation and operation as the example of the monolithic color-tunable LED system 10(1) except as otherwise illustrated or described herein.

In this example, growth on a sapphire substrate was utilized, although many alternative substrates could be utilized in other examples. Buffer layers 24 for strain engineering and defect reduction are first grown on the sapphire substrate, followed by the n-type GaN layer 12 as the source for electrons.

Next, the MQW region 16 is grown and includes eight (8) MQWs which are grown with 18% Indium containing layers acting as the quantum wells, which are grown on the n-GaN layer 12. These MQWs of the MQW region 16 can be grown directly on the n-GaN layer 12 or in another example on a super lattice to facilitate increased formation of the V-grooves 18(2a) and 18(2b) in this example. A super lattice is defined to be multiple InGaN—GaN quantum wells which contain a lower indium content.

Accordingly, as discussed earlier, during the growth of the MQW region 16, the V-grooves 18(2a) and 18(2b) are formed, initially below the MQW region 16 due to surface depressions caused by threading dislocations. Six {10^{1̅}1} crystal facets merge, forming the “V” shape grooves 18(2a) and 18(2b) in this example. Each of these V-grooves 18(2a) and 18(2b) bends the MQW layers of the MQW region 16 down, forming semi-polar quantum wells.

In this example, the larger V-grooves 18(2a) and 18(2b) are provided for both strain relaxation, modified current injection, and to edit the distribution of Indium. The V-grooves 18(2a) and 18(2b) are formed at the intersection between these two opposite charge regions, the p-type GaN layer 14 and n-type GaN layer 12, and where recombination of these charges happens in the InGaN layers of the MQW region 16 to produce light. The V-grooves 18(2a) and 18(2b) facilitate a way to easily inject charges into the InGaN layers of the MQW region 16, particularly at low currents. Combined with the mechanism that the V-grooves 18(2a) and 18(2b) modify the Indium content in each Indium Gallium Nitride (InGaN) layer in the MQW region 16 in or around each V-groove 18(2a) and 18(2b). The charges preferentially recombine initially in the Indium rich areas, leading to longer wavelength emission.

In this example, the maximum gap or gap distance at a top of the V-groove 18(2a) and 18(2b) is typically between 200-250 nm, tapering down to form the “V” shape. The V-grooves 18(2a) and 18(2b) are known to form due to growth temperature and strain as discussed earlier. These V-grooves 18(2a) and 18(2b) locally relax the crystal structure and can prevent threading dislocation defect propagation. The density of V-grooves can be modified depending on growth conditions and the structure.

After the V-grooves 18(2a) and 18(2b) and the MQW layers of the MQW region 16 are simultaneously grown, a p-type electron blocking layer (EBL) 20 is typically grown. As noted earlier, the EBL 20 can be a 5% Aluminum containing p-AlGaN layer, although other types and/or numbers of layers can be used. The EBL 20 is grown on the portion of the parallel layers in the V-grooves 18(2a) and 18(2b) and on the other portions of the parallel layers outside of the V-groove 18(1) of the MQW region 16. Next, a p-type GaN layer 14 is grown on top of the EBL 20, which also fills in the V-grooves 18(2a) and 18(2b), although other types and/or numbers of layers may be grown or otherwise added.

Accordingly, as illustrated by these examples the number of threading dislocation is determined by the growth structure and substrate. Growth of GaN based materials is done on a host substrate, such as sapphire by way of example, which leads to a lattice mismatch, creating defects, such as threading dislocations. The choice and technique in the grown of GaN based materials, such as GaN, InGaN, or AlGaN layers with their corresponding thickness and growth temperatures, can increase or decrease the level of threading dislocations. These threading dislocations can form the basis of V-groove formation during growth of the MQW region. Increased strain due to use of Indium to form InGaN layers along with corresponding lower growth temperatures, leads to the formation of the V-grooves which nucleate on the threading dislocation. Increased strain with increased Indium concentration can increase the nucleation of V-grooves.

In some examples of this technology, the density of the one or more V-grooves is optimized to be above 4×10⁸ cm⁻². Sizes of the one or more V-grooves can be controlled through engineering the strain related to the foundational layer that the MQW region is in contact with and grown on. Use of a super lattice, which contains multiple InGaN/GaN layers with lower Indium content than the MQW region or use of GaN grown at low temperatures can facilitate the creation of larger V-groove gap distances.

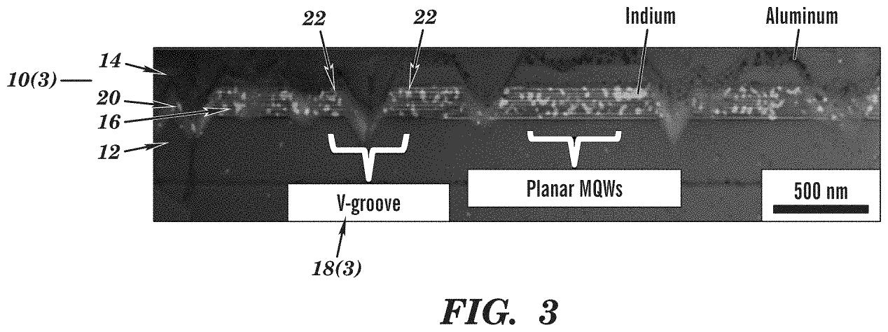

Referring to FIG. 3, a cross-sectional image of another example of monolithic color-tunable LED system 10(3) overlaid with rough estimates on the areas of Indium and Aluminum is illustrated. This example of the monolithic color-tunable LED system 10(3) is the same in structure, formation and operation as the example of the monolithic color-tunable LED system 10(1) except as otherwise illustrated or described herein. This example of the monolithic color-tunable LED system 10(3) is formed with multiple V-grooves, but for ease of discussion V-groove 18(3) will be referred to below and the discussion in this example is applicable to the other V-grooves.

As shown in FIG. 3, less Indium is present in the semi-polar MQWs formed by the V-groove 18(3), compared to the portions of the parallel layers a distance outside the V-groove 18(3) (also referred to as the planar MQWs) in the MQW region 16. This is not the case for Aluminum containing layers, which maintain approximate equal distribution. In this example, the sides of the V-groove 18(3) are surfaces of semi-polar crystal planes which contain less Indium due to differences in the Indium sticking coefficient during growth. The semi-polar MQWs of the portion of the parallel layers of the MQW region 16 in the V-groove 18(3) are also thinner than the planar MQWs or other portion of the parallel layers of the MQW region 16. The decrease of Indium in the portion of the parallel layers of the MQW region 16 in the V-groove 18(3), relative to the designed planar MQWs, other portion of the parallel layers of the MQW region 16 is accompanied by an Indium rich “region of transition” or transition region 22 formed in MQWs of the MQW region 16 adjacent to the V-groove 18(3). Indium concentration is highest at the periphery of a V-groove 18(3) and declines with distance from the V-groove 18(3) to the level of Indium doping originally incorporated in the designed planar MQWs. In this example, whereas the Indium poor semi-polar MQWs of the MQW region 16 inside the V-groove 18(3) may have 5-15% Indium, the planar MQWs of the MQW region 16 in each of the transition regions 22 nearest the V-groove 18(1) have Indium concentrations as high as 30-50%, declining in concentration to the designed 18% Indium in the other portion of the parallel layers of the MQW region 18 with increasing distance from the V-groove 18(3). This localized increase of Indium is not detrimental to electron-hole recombination efficiency, as is the case with intentionally high Indium content growth for continuous planar MQWs, as these localized increased regions are strain relaxed due to the V-groove 18 (3).

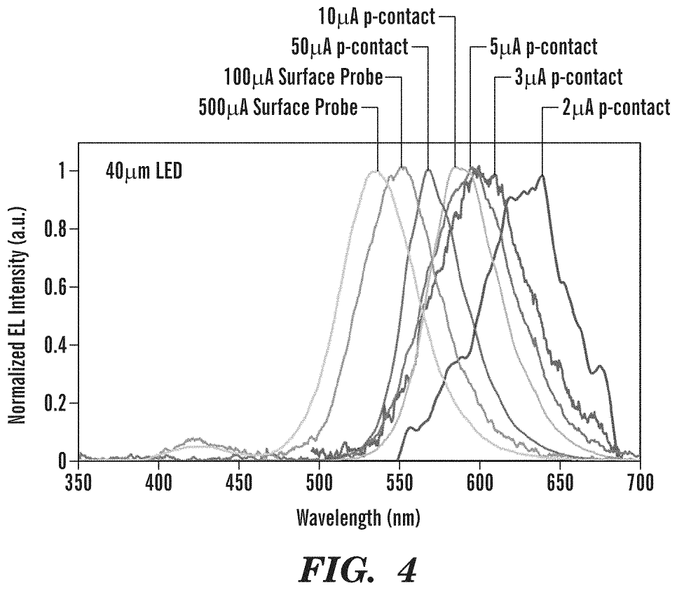

Referring to FIG. 4, a graph of various current densities utilized in order to produce different desired color emissions from ˜640 nm down to ˜425 nm to span the visible spectrum, with one of the monolithic color-tunable LED systems 10(1)-10(3) as described in examples of this technology is illustrated. In this example, low current density applied to one of the monolithic color-tunable LED systems 10(1)-10(3) produces red emission and emission is significantly blue-shifted with increasing current. Accordingly, this causes the colors to change from red to orange, to yellow, to green, and then to blue. For smaller LEDs the color emission change requires less current compared to larger LEDs, as smaller LEDs will have a greater current density. The emission characteristics are also modified due to the Indium percentage formed in the various identified regions, forming a range of possible color emission from blue to red.

This emission range can be tuned with each color end emitting longer or shorter wavelengths, depending on the planar Indium percentage utilized. Increased Indium percentage, such as 25% in the planar MQWs of the MQW region 16 increases the inclusion of Indium in the semi-polar MQWs of the portion of the MQW region 16 in the V-grooves, as well as the localized Indium composition in the planar MQW near to the V-groove. This shifts the total range of optical wavelengths able to be generated from one of the monolithic color-tunable LED systems 10(1)-10(3) to longer wavelengths. In contrast, if the designed planar MQW Indium percentage of the portion of the MQW region 16 in the V-grooves is decreased, such as to 15%, V-groove incorporation at the same density would similarly shift the range of wavelengths generated to shorter values on each end. Where less Indium is incorporated into the semi-polar MQWs of the portion of the MQW region 16 in the V-grooves, the corresponding Indium rich regions or transition regions 22 of the MQW region 16 also contain less Indium.

Accordingly, with examples of this technology to operate an LED formed in one of the exemplary monolithic color-tunable LED systems 10(1)-10(3), a positive bias is applied to the anode, while the cathode is held at ground. Alternatively, the cathode can held at a negative bias, with respect to the grounded p-type contact by way of example. Application of this bias injects holes from the p-type GaN region 14 into the MQWs in the MQW region 16 to recombine with electrons and produce light. However, before this occurs the holes must first overcome an energy barrier provided by the EBL 20. Use of the EBL 20 between the p-type GaN layer 14 and the MQW region 16 creates a large barrier for electrons while creating a smaller barrier for holes. The semi-polar planes of the V-grooves in one of the exemplary monolithic color-tunable LED systems 10(1)-10(3) have reduced internal piezoelectric fields which lessens the barrier to holes provided by the EBL 20. Thereby, holes (h+) are more easily able to be injected laterally rather than vertically as shown by the arrow in the example in FIG. 1.

As illustrated in FIG. 4, at low current density, the Indium rich areas near the V-grooves in one of the exemplary monolithic color-tunable LED systems 10(1)-10(3) first populate leading to red emission. As the current and correspond voltage increase, the carriers are further spread, combined with a possible carrier screening effect. As the voltage increases, the energy bands bend such that the vertical hole injection barrier is reduced, and vertical hole injection can dominate. As the current density increases, the carriers spread populating the less Indium rich areas leading to orange, yellow, green, and then blue emission.

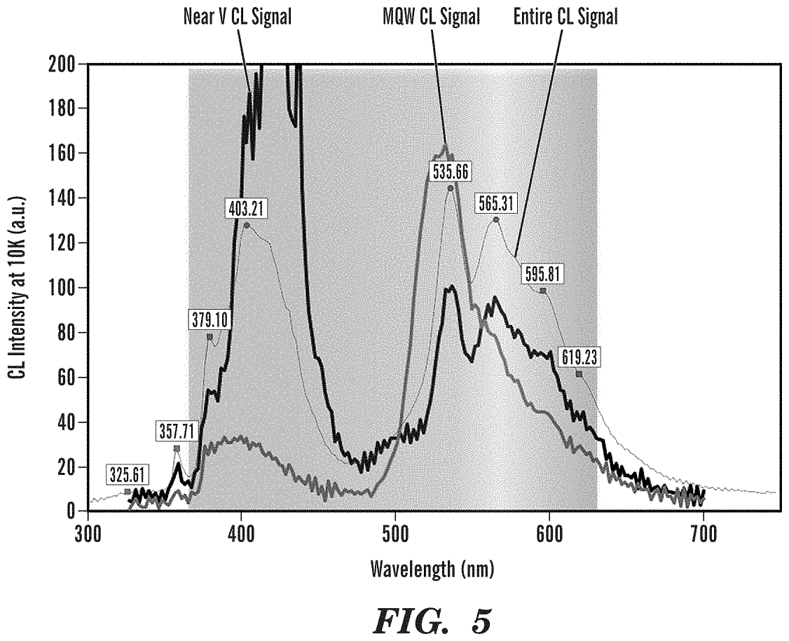

Referring to FIG. 5, a graph of cathode luminescence (CL) emission is shown from around a V-groove and the MQWs away from any of the V-grooves in one of the exemplary monolithic color-tunable LED systems 10(1)-10(3). The peaks are blue shifted due to the measurements being taken at a temperature of 10K. The red (600 nm, 619 nm), yellow (565 nm), and green (535 nm) emission appears through separate peaks located in the regions of transition due to the aforementioned modified Indium incorporation above the 18% contained in the planar MQW region. The large blue peak (400 nm, 425 nm) occurs along the sides of the one or more V-grooves in one of the exemplary monolithic color-tunable LED systems 10(1)-10(3), due to the lower incorporation of Indium around 5-10%. In contrast, the portion of the MQW region 16 in one of the exemplary monolithic color-tunable LED systems 10(1)-10(3) located beyond transition regions 22 shows expected green emission centered at 535 nm. The MQW region 16 in one of the exemplary monolithic color-tunable LED systems 10(1)-10(3) located beyond the transition regions 22 also show a ˜400 nm peak which could be from population of a first excited state in the eight 18% InGaN QWs.

The blue emission from one of the monolithic color-tunable LED systems 10(1)-10(3) can be further engineered through a number of optimizations. One such optimization involves shrinking down the diameter of the LED in one of the exemplary monolithic color-tunable LED systems 10(1)-10(3), which leads to increased blue emission. As the LED diameter shrinks, the current and voltage further concentrate which modifies the internal energy bands in the LED in one of the exemplary monolithic color-tunable LED systems 10(1)-10(3). By way of example, sub 10 μm LEDs can be utilized to achieve a greater amount of shorter wavelength emission from one of the monolithic color-tunable LED systems 10(1)-10(3). Additional techniques, such as increased V-groove concentrations, non-ohmic anode and cathode contacts, and inclusion of additional 5-15% Indium quantum wells are all alternative techniques which can be employed separately or together for optimizing greater amounts of shorter wavelength emission in one of the exemplary monolithic color-tunable LED systems 10(1)-10(3).

Accordingly, as illustrated and described by way of the examples herein, examples of this technology provide a monolithic multi-color LED system which may be effectively utilized in a number of different applications, such as displays, commercial lighting, communications, and more. In particular, examples of this technology provide a monolithic integration of color-selectable LEDs without requiring any color converters which reduces complexity, offers better performance, and lowers cost for many applications. Monolithic is defined for some examples herein as the same InGaN/GaN, III-N, material system used within the same wafer. Examples of the claimed technology are further able to provide monolithic color-tunable LEDs without Eu doping, growth of separate MQW regions, or increased planar Indium percentage. Further, with examples of this technology LEDs as small as two (2) microns in diameter having at least one V-groove contained within can be manufactured.

Having thus described the basic concept of the technology, it will be rather apparent to those skilled in the art that the foregoing detailed disclosure is intended to be presented by way of example only and is not limiting. Various alterations, improvements, and modifications will occur and are intended to those skilled in the art, though not expressly stated herein. These alterations, improvements, and modifications are intended to be suggested hereby, and are within the spirit and scope of the technology. Additionally, the recited order of processing elements or sequences, or the use of numbers, letters, or other designations therefore, is not intended to limit the scope of the present invention.

What is claimed is:

1. A monolithic LED system configured to emit a variety of peak wavelengths of light in response to variations in a driving current density, the system comprising:
an n-type region;
a p-type region;
a multiple quantum well (MQW) region formed between the n-type region and the p-type region, wherein the MQW region comprises:
parallel layers each doped with a percentage of Indium to enable a range of light emission between 400 and 600 nm, and
one or more V-grooves formed within a portion of the parallel layers, wherein a portion of the parallel layers in each of the one or more V-grooves has a lower concentration of the doped percentage of the Indium than other portions of the parallel layers and wherein transition regions between the portion of the parallel layers in each of the one or more V-grooves and the other portions of the parallel layers has a higher concentration of the doped percentage of the Indium which decreases with distance from the one or more V-grooves.

2. The monolithic LED system as set forth in claim 1, wherein the parallel InGaN layers are each doped with the percentage of the Indium to favor green light emission.

3. The monolithic LED system as set forth in claim 1, wherein the parallel InGaN layers are each doped with the percentage of the Indium to favor cyan light emission.

4. The monolithic LED system as set forth in claim 1, wherein the parallel InGaN layers are each doped with the percentage of the Indium to favor orange light emission.

5. The monolithic LED system as set forth in claim 1, wherein the parallel layers include more than 2×10⁸ cm⁻² of the one or more V-grooves.

6. The monolithic LED system as set forth in claim 1, wherein each of the one or more V-grooves has a maximum gap width below 10 microns.

7. The monolithic LED system as set forth in claim 1, wherein each of the one or more V-grooves has a maximum gap width between 100 and 350 nm.

8. The monolithic LED system as set forth in claim 1, wherein a percentage of the concentration of the Indium within the one or more V-grooves is between five percent and fifteen percent.

9. The monolithic LED system as set forth in claim 1, wherein a maximum percentage of the concentration of the Indium at the transition regions is 100% percent.

10. The monolithic LED system as set forth in claim 1, further comprising an electron blocking layer adjacent to the MQW region.

11. The monolithic LED system as set forth in claim 1 wherein the multilayer semiconductor material with the one or more V-grooves is two (2) microns in diameter.

12. A method for making a monolithic LED system configured to emit a variety of peak wavelengths of light in response to variations in a driving current density, the method comprising:
forming one of an n-type region or p-type region;
forming a multiple quantum well (MQW) region on the one of the n-type region or the p-type region, wherein the MQW region comprises:
parallel layers, each doped with a percentage of Indium to enable a range of light emission between 400 and 600 nm; and
one or more V-grooves formed within a portion of the parallel layers;
wherein a portion of the parallel layers in each of the one or more V-grooves has a lower concentration of the doped percentage of the Indium than other portions of the parallel layers; and
wherein transition regions between the portion of the parallel layers in each of the one or more V-grooves and the other portions of the parallel layers has a higher concentration of the doped percentage of the Indium which decreases with distance from the one or more V-grooves
forming the other one of the n-type region or the p-type region on the MQW region.

13. The method as set forth in claim 12, wherein the parallel InGaN layers are each doped with the percentage of the Indium to favor green light emission.

14. The method as set forth in claim 12, wherein the parallel InGaN layers are each doped with the percentage of the Indium to favor cyan light emission.

15. The method as set forth in claim 12, wherein the parallel InGaN layers are each doped with the percentage of the Indium to favor orange light emission.

16. The method as set forth in claim 12, wherein the parallel layers include more than 2×10⁸ cm⁻² of the one or more V-grooves.

17. The method as set forth in claim 12, wherein each of the one or more V-grooves has a maximum gap width below 10 microns.

18. The method as set forth in claim 12, wherein each of the one or more V-grooves has a maximum gap width between 100 and 350 nm.

19. The method as set forth in claim 12, wherein a percentage of the concentration of the Indium within the one or more V-grooves is between five percent and fifteen percent.

20. The method as set forth in claim 12, wherein a maximum percentage of the concentration of the Indium at the transition regions is 100% percent.

21. The method as set forth in claim 12, further comprising:
forming an electron blocking layer adjacent to the MQW region.

22. The method as set forth in claim 12 wherein the multilayer semiconductor material with the one or more V-grooves is two (2) microns in diameter.
